(19) United States
(12) Patent Application Publication
(10) Pub. No.: US 2025/0281947 A1
(43) Pub. Date: Sep. 11, 2025

(54) DEPOSITING APPARATUS AND CLEANING METHOD OF THE SAME

(71) Applicant: Samsung Display Co., LTD., Yongin-si (KR)

(72) Inventor: Myung Kyu KIM, Yongin-si (KR)

(73) Assignee: Samsung Display Co., LTD., Yongin-si (KR)

(21) Appl. No.: 18/953,505

(22) Filed: Nov. 20, 2024

(30) Foreign Application Priority Data
Mar. 6, 2024 (KR) 10-2024-0031995

(51) Int. Cl. B08B 7/00; B08B 9/027; C23C 14/24

(52) U.S. Cl. CPC B08B 7/0071; B08B 9/027; C23C 14/24; B08B 2209/027

(57) ABSTRACT

A depositing apparatus includes a deposition source including at least one deposition nozzle that spray a deposition material, a spray angle limiting portion spaced apart from the deposition source and limiting a spray angle of the deposition material sprayed from the at least one deposition nozzle, and a cleaning module disposed between the deposition source and the spray angle limiting portion and heating the deposition material accumulated on the spraying angle limiting portion.

### CROSS-REFERENCE TO RELATED APPLICATION(S)

This application claims priority to and benefits of Korean Patent Application No. 10-2024-0031995 under 35 U.S.C. § 119, filed on Mar. 6, 2024, in the Korean Intellectual Property Office (KIPO), the entire contents of which are incorporated herein by reference.

### BACKGROUND

### 1. Technical Field

The disclosure relates to a depositing apparatus and a cleaning method of the same.

### 2. Description of the Related Art

An organic light emitting display device is a display device using a phenomenon in which electrons injected from a cathode and holes injected from an anode recombine in an organic thin film to form excitons, and light of a specific wavelength is generated by energy from the formed excitons.

As a method of depositing organic materials or metals used as electrodes in the organic light emitting display device, a vacuum deposition method using a depositing apparatus may be used. The vacuum deposition method may be performed by positioning a substrate on which an organic thin film is to be formed inside a vacuum chamber, making a deposition mask having the same pattern as a pattern of the thin film to be formed in close contact with the substrate, and depositing a deposition material on the substrate by evaporating or sublimating the deposition material such as an organic material using a deposition source.

A spray angle limiting portion for limiting a spray angle of a deposition material sprayed from a deposition nozzle of the deposition source may be disposed in the deposition apparatus in which the vacuum deposition method is performed. During the process of depositing the deposition material, as the deposition material accumulates in the spray angle limiting portion, the spray angle of the deposition material sprayed from the deposition nozzle may change. In addition, the deposition material accumulated on the spray angle limiting portion may fall and thus close the deposition nozzle.

### SUMMARY

Aspects of the disclosure provide a depositing apparatus capable of preventing a spray angle of a deposition material from changing by preventing the deposition material from being accumulated on a spray angle limiting portion, and ensuring continuous operation of a deposition process by cleaning the deposition material that closes a deposition nozzle, and a cleaning method of the same.

However, embodiments of the disclosure are not limited to those set forth herein. The above and other embodiments of the disclosure will become more apparent to one of ordinary skill in the art to which the disclosure pertains by referencing the detailed description of the disclosure given below.

According to an embodiment of the disclosure, a depositing apparatus may include a deposition source including at least one deposition nozzle that sprays a deposition material, a spray angle limiting portion spaced apart from the deposition source and limiting a spray angle of the deposition material sprayed from the at least one deposition nozzle, and a cleaning module disposed between the deposition source and the spray angle limiting portion and heating the deposition material accumulated on the spraying angle limiting portion.

The cleaning module may be disposed closer to the spray angle limiting portion than the deposition source.

The at least one deposition nozzle may include a plurality of deposition nozzles, the plurality of deposition nozzles may be arranged in a first direction, and the cleaning module may be disposed to be movable in the first direction.

The spray angle limiting portion may include an extension plate extending to an upper direction from the deposition source, and a blocking plate extending from the extension plate in a second direction and forming an open area through which the deposition material passes.

The second direction may be a direction horizontally orthogonal to the first direction.

The open area may be disposed above the plurality of deposition nozzles and extend in the first direction.

The cleaning module may include, a moving rail extending in the first direction below the blocking plate, a moving block disposed on the moving rail and moving along the moving rail, and a heating member extending from the moving block in the second direction.

The cleaning module may further include a first driver connecting the moving block and the heating member and moving the heating member in the second direction.

The cleaning module may further include a second driver connecting the first driver and the heating member and rotating the heating member so that an extended end of the heating member faces a third direction.

The third direction may be a direction vertically orthogonal to the first direction and the second direction.

The cleaning module may further include a third driver connecting the second driver and the heating member and moving the heating member in the third direction.

The heating member may be moved by the third driver and inserted into one of the plurality of deposition nozzles.

The extension plate may include a plurality of extension plates, the plurality of extension plates may include a first extension plate and a second extension plate, the first extension plate may extend in an upper direction from a side of the deposition source, and the second extension plate may extend in an upper direction from another side of the deposition source so that the plurality of deposition nozzles are disposed between the first extension plate and the second extension plate.

The blocking plate may include a plurality of blocking plates, the plurality of blocking plates may include a first blocking plate and a second blocking plate, the first blocking plate may extend from the first extension plate in the second direction so as to be directed to an upper side of the plurality of deposition nozzles, the second blocking plate may extend from the second extension plate in the second direction to face the first blocking plate, and an extended end of the first blocking plate and an extended end of the second blocking plate may be spaced apart from each other, so that the open area is formed between the first blocking plate and the second blocking plate.

The cleaning module may include a plurality of cleaning modules, the plurality of cleaning modules may include a first cleaning module and a second cleaning module, the first cleaning module may be disposed below the first blocking plate, and the second cleaning module may be disposed below the second blocking plate.

According to an embodiment of the disclosure, a cleaning method of a depositing apparatus may include cleaning a spray angle limiting portion including moving a cleaning module disposed below the spray angle limiting portion that limits a spray angle of a deposition material sprayed from a deposition nozzle along the spray angle limiting portion, and removing the deposition material accumulated on the spray angle limiting portion by a heating member of the cleaning module, and cleaning the deposition nozzle including inserting the heating member into the deposition nozzle to remove the deposition material accumulated in the deposition nozzle.

The deposition nozzle may include a plurality of deposition nozzles arranged in a first direction, the spray angle limiting portion may include a blocking plate that forms an open area through which the deposition material passes extending in the first direction above the plurality of deposition nozzles, and the cleaning of the spray angle limiting portion may include moving the cleaning module in the first direction below the blocking plate.

The cleaning module may further include, a moving rail extending in the first direction below the blocking plate, and a moving block supporting the heating member and disposed on the moving rail to move along the moving rail, and the cleaning of the spray angle limiting portion may include moving the moving block along the moving rail.

The cleaning module may further include, a first driver moving the heating member in a second direction horizontally orthogonal to the first direction and positioning the heating member above the plurality of deposition nozzles, a second driver rotating the heating member to a third direction vertically orthogonal to the first direction and the second direction so that the heating member faces the plurality of deposition nozzles, and a third driver moving the heating member in the third direction so that the heating member is inserted into one of the plurality of deposition nozzles. The cleaning of the deposition nozzle may further include, moving the heating member in the second direction by the first driver and positioning the heating member above the plurality of deposition nozzles, rotating the heating member positioned above the one of the plurality of deposition nozzles by the second driver to face the one of the plurality of deposition nozzles, and inserting the heating member rotated to face the one of the plurality of deposition nozzles into the one of the plurality of deposition nozzles by the third driver.

The cleaning of the deposition nozzle may further include, moving the heating member inserted into the one of the plurality of deposition nozzles in the third direction by the third driver so that the heating member is pulled out from the one of the plurality of deposition nozzles, moving the moving block along the moving rail so that the heating member pulled out from the one of the plurality of deposition nozzles is positioned above another one of the plurality of deposition nozzles adjacent to the one of the plurality of deposition nozzles, and inserting the heating member positioned above the another one of the plurality of deposition nozzles into the another one of the plurality of deposition nozzles by the third driver.

According to the depositing apparatus and the cleaning method of the same according to the disclosure, it is possible to prevent the spray angle of the deposition material from changing by preventing the deposition material from being accumulated on the spray angle limiting portion, and to ensure continuous operation of the deposition process by cleaning the deposition material that closes the deposition nozzle.

The effects according to the embodiments of the disclosure are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic cross-sectional view illustrating a depositing apparatus according to an embodiment of the disclosure;

FIG. 2 is a plan view illustrating a deposition source, a spray angle limiting portion, and a cleaning module of FIG. 1;

FIG. 3 is a left side view of FIG. 2;

FIG. 4 is a right side view of FIG. 2;

FIG. 5 is a schematic cross-sectional view illustrating a state in which a first driver is driven in the front view of FIG. 2;

FIG. 6 is a schematic cross-sectional view illustrating a state in which a second driver is driven in FIG. 5;

FIG. 7 is a schematic cross-sectional view illustrating a state in which a third driver is driven in FIG. 6;

FIG. 8 is a schematic cross-sectional view illustrating a state in which a spray angle of a deposition nozzle is changed due to a deposition material accumulated on the spray angle limiting portion of FIG. 1;

FIG. 9 is a plan view illustrating a state in which a first cleaning module and a second cleaning module in FIG. 2 are moved in a first direction;

FIG. 10 is a schematic cross-sectional view illustrating a state in which a heating member is moved in a second direction by the first driver in the front view of FIG. 2;

FIG. 11 is a schematic cross-sectional view illustrating a state in which the heating member is rotated to face a third direction by the second driver in FIG. 10;

FIG. 12 is a schematic cross-sectional view illustrating a state in which the heating member is moved in the third direction by the third driver in FIG. 11 and inserted into a deposition nozzle;

FIG. 13 is a schematic cross-sectional view illustrating a state in which the heating member is moved in the third direction by the third driver in FIG. 12 and pulled out from the deposition nozzle;

FIG. 14 is a schematic cross-sectional view illustrating a state in which a first moving block is moved in the first direction along a first moving rail in the left side view of FIG. 13; and

FIG. 15 is a schematic cross-sectional view illustrating a state in which the heating member is moved in the third direction by the third driver in FIG. 14 and inserted into another deposition nozzle.

### DETAILED DESCRIPTION OF THE EMBODIMENTS

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure thorough and for fully conveying the scope of the disclosure to those skilled in the art. It is to be noted that the scope of the disclosure is defined only by the claims.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. Like reference numerals denote like elements throughout the descriptions.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

Features of various embodiments of the disclosure may be combined partially or totally. As will be clearly appreciated by those skilled in the art, technically various interactions and operations are possible. Various embodiments can be practiced individually or in combination.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

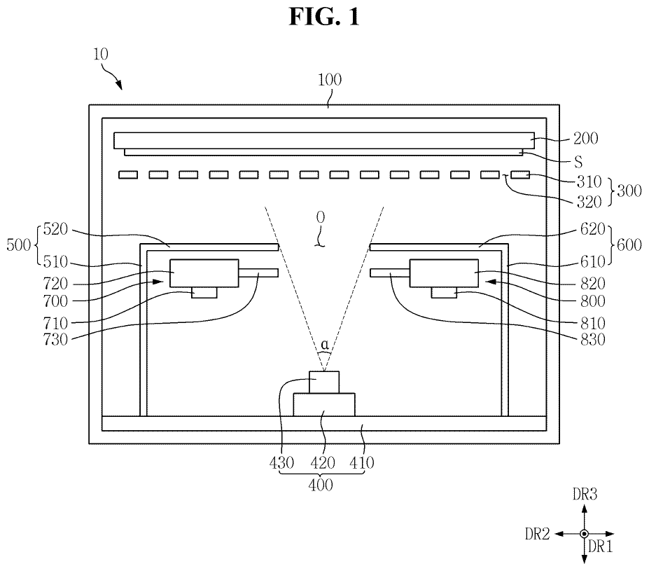

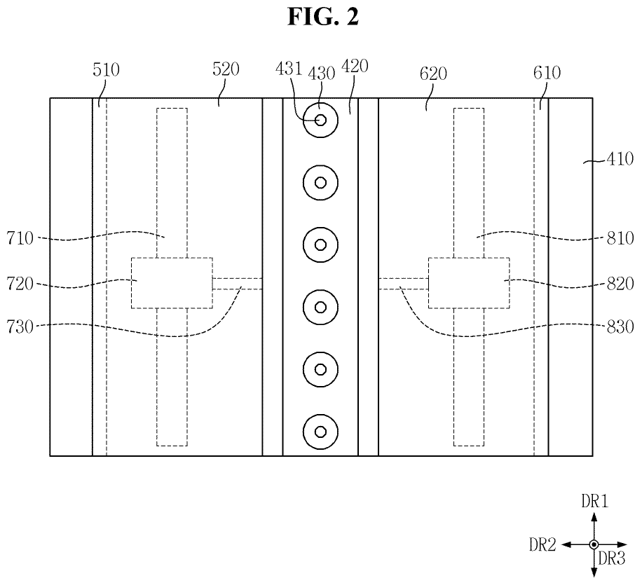

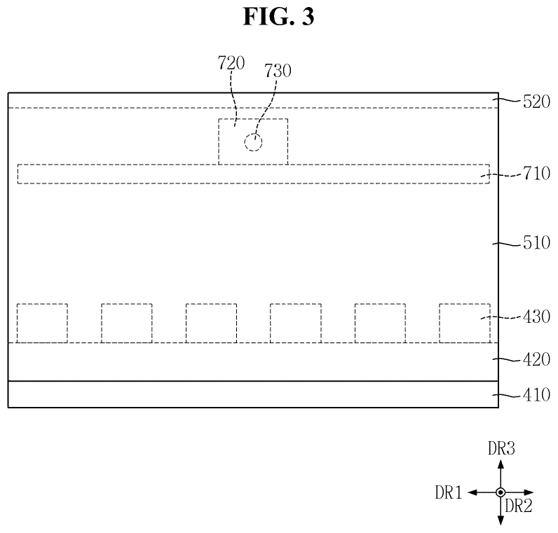

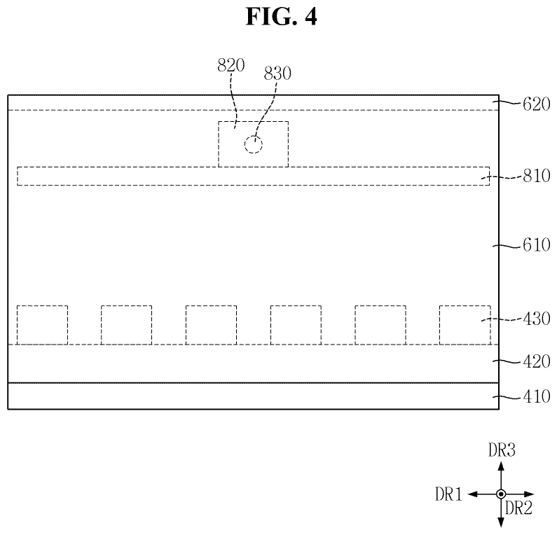

FIG. 1 is a schematic cross-sectional view illustrating a depositing apparatus 10 according to an embodiment of the disclosure. FIG. 2 is a plan view illustrating a deposition source 400, a spray angle limiting portion, and a cleaning module of FIG. 1. FIG. 3 is a left side view of FIG. 2. FIG. 4 is a right side view of FIG. 2.

Referring to FIGS. 1 to 4, the depositing apparatus 10 according to an embodiment of the disclosure may deposit an organic material or a metal used as an electrode on a substrate S. The depositing apparatus 10 may include a chamber 100, a substrate holder 200, a mask assembly 300, a deposition source 400, a spray angle limiting portion, and a cleaning module.

The chamber 100 may provide a space in which a deposition process is performed. The interior of the chamber 100 may be maintained in a vacuum while performing the deposition process. Maintaining the interior of the chamber 100 in a vacuum may mean maintaining a pressure inside the chamber 100 at a low pressure. The chamber 100 may include a port (not illustrated) for porting in and out of the substrate S. The chamber 100 may further include a vacuum pump (not illustrated) for controlling the pressure inside the chamber 100 and exhausting the deposition material not deposited on the substrate S, and an exhaust port (not illustrated) connected to the vacuum pump.

The substrate S on which the organic material or the metal used as the electrode is deposited may be provided as an insulating substrate, a semiconductor substrate, a display substrate, etc., but is not limited thereto. In the disclosure, a substrate S used in an organic light emitting display device will be described as an embodiment. A structure may be formed on the substrate S through a deposition process. Depending on a process of manufacturing an organic light emitting display device, the structure formed on the substrate S through the deposition process may be formed in various ways. For example, in a process of forming a hole injection layer, a pixel defining film and an anode electrode may be formed on the substrate S. In a process of forming an organic light emitting layer, a hole injection layer and a hole transport layer as well as a pixel defining layer and an anode electrode may be formed on the substrate S.

The substrate holder 200 may support the substrate S. The substrate holder 200 may be disposed inside the chamber 100. In an embodiment, the substrate holder 200 may be disposed on an upper side inside the chamber 100, and the substrate S may be seated on a lower portion of the substrate holder 200 and supported by the substrate holder 200. The substrate holder 200 may include a fixing member (not illustrated). The fixing member may assist in fixing the substrate S and the mask assembly 300, and may serve to maintain a constant distance between the substrate S and the mask assembly 300. The fixing member may be provided as a frame structure that may be separately mounted.

The mask assembly 300 may define an area where the deposition material sprayed from the deposition source 400 is deposited on the substrate S. The mask assembly 300 may include a mask portion 310, a transmission portion 320, and a mask side wall portion (not illustrated). The mask portion 310 may cover a partial area of the substrate S to prevent the deposition material sprayed from the deposition source 400 from being deposited on the corresponding area. The transmission portion 320, which is an area that exposes a partial area of the substrate S, may be an open area formed between the mask portions 310. The deposition material may be sprayed onto an exposed area of the substrate S exposed by the transmission portion 320 and deposited on the exposed area of the substrate S. Therefore, the deposition material sprayed from the deposition source 400 may be deposited on the substrate S while forming a pattern through the mask assembly 300. The mask side wall portion may be positioned in an edge area of the mask assembly 300 to prevent the deposition material from spreading to areas other than the substrate S. The mask assembly 300 may be a raw mask such as a fine metal mask (FMM) or multiple segmented masks, but is not limited thereto. The mask assembly 300 may be disposed close to and fixed to the substrate S, and a distance between the mask assembly 300 and the substrate S may be adjusted by the substrate holder 200 and the fixing member.

The deposition source 400 may provide a deposition material to be deposited on the substrate S. The deposition source 400 may be disposed inside the chamber 100, and may be disposed to face the substrate S. In an embodiment, in case that the substrate holder 200 on which the substrate S is seated is disposed on an upper side inside the chamber 100, the deposition source 400 may be disposed on a lower side inside the chamber 100. The deposition source 400 may include a base plate 410, a deposition nozzle supporter 420, and a deposition nozzle 430.

The base plate 410 may support at least one of the deposition nozzle supporter 420 and the deposition nozzle 430. The base plate 410 may be disposed on a lower side inside the chamber 100. The base plate 410 may be provided as a plate with a thickness, may be disposed so that a lower surface is in contact with an inner lower surface of the chamber 100, and may have the deposition nozzle supporter 420 disposed on an upper surface to support the deposition nozzle supporter 420.

The deposition nozzle supporter 420 may support the deposition nozzle 430. The deposition nozzle supporter 420 may be disposed on the upper surface of the base plate 410 and supported by the base plate 410. The deposition nozzle supporter 420 may be provided as a block having a thickness and may be formed on the upper surface of the base plate 410 to extend in a first direction DR1.

The deposition nozzle 430 may spray the deposition material and supply the deposition material to the substrate S. The deposition nozzle 430 may be disposed on the upper surface of the deposition nozzle supporter 420 and supported by the deposition nozzle supporter 420. Multiple deposition nozzles 430 may be provided and arranged to be spaced apart from each other along the first direction DR1 on the upper surface of the deposition nozzle supporter 420. The deposition nozzle 430 may be connected to a deposition material storage unit (not illustrated) and may spray the deposition material stored in the deposition material storage unit. The deposition nozzle 430 may supply the deposition material to the substrate S by spraying the deposition material in an upper direction. In other words, the deposition nozzle 430 may spray the deposition material to an upper side in a third direction DR3. A spray passage 431 may be formed in the center of the deposition nozzle 430, and the deposition material may be sprayed through the spray passage 431.

The spray angle limiting portion may be disposed to be spaced apart from the deposition source 400 to limit a spray angle of the deposition material sprayed from the deposition nozzle 430. The spray angle limiting portion may adjust the area and thickness where the deposition material is deposited by limiting the spray angle of the deposition material sprayed from the deposition nozzle 430. Multiple spray angle limiting portions may be provided. The spray angle limiting portions may include a first spray angle limiting portion 500 and a second spray angle limiting portion 600.

The first spray angle limiting portion 500 may be disposed on the left side (left side in FIG. 1) of the deposition source 400 in a second direction DR2 and block a portion of the deposition material sprayed from the deposition nozzle 430, thereby adjusting the spray angle of the deposition material. The first spray angle limiting portion 500 may include a first extension plate 510 and a first blocking plate 520. The second direction DR2 may be defined as a direction horizontally orthogonal to the first direction DR1.

The first extension plate 510 may extend in an upper direction from the base plate 410 and may support the first blocking plate 520. The first extension plate 510 may be disposed on the left side (left side in FIG. 1) of the deposition nozzle 430. The first extension plate 510 may be provided as a plate having a thickness and may extend along the first direction DR1 on the upper surface of the base plate 410. An extended length of the first extension plate 510 may correspond to an extended length of the deposition nozzle supporter 420.

The first blocking plate 520 may extend from an upper end of the first extension plate 510 to the right side (right side in FIG. 1) in the second direction DR2 and may block a portion of the deposition material sprayed from the deposition nozzle 430. The first blocking plate 520 may be provided as a plate having a thickness and may extend from the upper end of the first extension plate 510 along the first direction DR1. An extended length of the first blocking plate 520 may correspond to an extended length of the deposition nozzle supporter 420.

The second spray angle limiting portion 600 may be disposed on the right side (right side in FIG. 2) of the deposition source 400 in the second direction DR2 and block a portion of the deposition material sprayed from the deposition nozzle 430, thereby adjusting the spray angle of the deposition material. The second spray angle limiting portion 600 may include a second extension plate 610 and a second blocking plate 620.

The second extension plate 610 may extend in an upper direction from the base plate 410 and may support the second blocking plate 620. The second extension plate 610 may be disposed on the right side (right side in FIG. 1) of the deposition nozzle 430. The second extension plate 610 may be provided as a plate having a thickness and may extend along the first direction DR1 on the upper surface of the base plate 410. An extended length of the second extension plate 610 may correspond to an extended length of the deposition nozzle supporter 420.

The second blocking plate 620 may extend from an upper end of the second extension plate 610 to the left side (left side in FIG. 1) in the second direction DR2 and may block a portion of the deposition material sprayed from the deposition nozzle 430. The second blocking plate 620 may be provided as a plate having a thickness and may extend from the upper end of the second extension plate 610 along the first direction DR1. An extended length of the second blocking plate 620 may correspond to an extended length of the deposition nozzle supporter 420. An end of the second blocking plate 620 in the second direction DR2 may be spaced apart from an end of the first blocking plate 520 in the second direction DR2. In other words, as the end of the first blocking plate 520 in the second direction DR2 and the end of the second blocking plate 620 in the second direction DR2 are spaced apart from each other, an open area O may be formed between the first blocking plate 520 and the second blocking plate 620. The open area O may be an area through which the deposition material passes. As a portion of the deposition material is blocked by the first blocking plate 520 and the second blocking plate 620 and the deposition material passes through the open area O, a spray angle α of the deposition material sprayed from the deposition nozzle 430 may be limited. The spray angle a of the deposition material may be changed by adjusting the extended length of the first extension plate 510 and the second extension plate 610 in the third direction DR3, or adjusting the extended length of the first blocking plate 520 and the second blocking plate 620 in the second direction DR2. The open area O may be disposed above the deposition nozzle 430 and may extend along the first direction DR1.

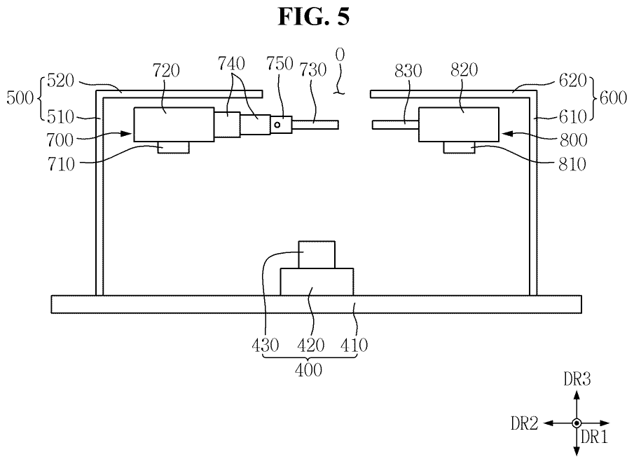

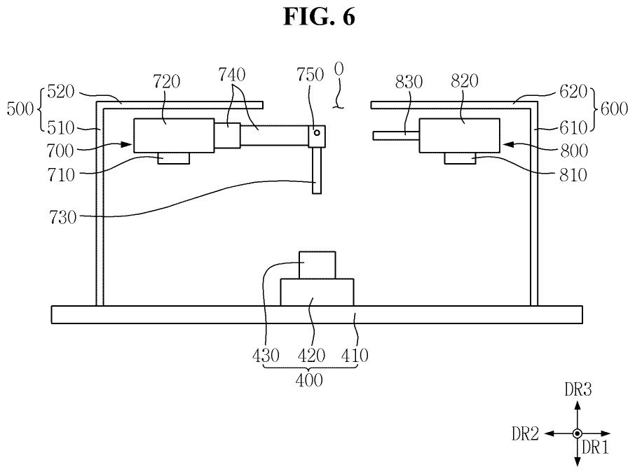

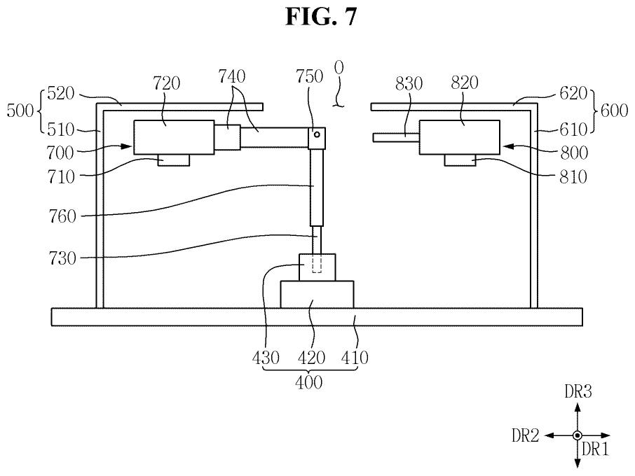

FIG. 5 is a schematic cross-sectional view illustrating a state in which a first driver is driven in the front view of FIG. 2. FIG. 6 is a schematic cross-sectional view illustrating a state in which a second driver is driven in FIG. 5. FIG. 7 is a schematic cross-sectional view illustrating a state in which a third driver is driven in FIG. 6.

Referring further to FIGS. 5 to 7, the cleaning module may be disposed to be movable along the spray angle limiting portion between the deposition source 400 and the spray angle limiting portion. The cleaning module may be disposed close to the spray angle limiting portion and move along the spray angle limiting portion, thereby removing the deposition material accumulated on the spray angle limiting portion. The cleaning module may be disposed to be movable in the first direction DR1. Multiple cleaning modules may be provided. The cleaning modules may include a first cleaning module 700 and a second cleaning module 800.

The first cleaning module 700 may remove the deposition material accumulated on the first blocking plate 520. The first cleaning module 700 may remove the deposition material accumulated in the spray passage 431 of the deposition nozzle 430. The first cleaning module 700 may be disposed below the first blocking plate 520. The first cleaning module 700 may include a first moving rail 710, a first moving block 720, a first heating member 730, a first driver 740, a second driver 750, and a third driver 760.

The first moving rail 710 may provide a path along which the first moving block 720 moves. The first moving rail 710 may be disposed below the first blocking plate 520 to be spaced apart from the first blocking plate 520 by a distance. The first moving rail 710 may extend in the first direction DR1 along the first blocking plate 520. In other words, the first moving rail 710 may extend from a side (lower side in FIG. 2) of the first blocking plate 520 in the first direction DR1 to another side (upper side in FIG. 2) of the first blocking plate 520 in the first direction DR1. An extended length of the first moving rail 710 may be less than the extended length of the first blocking plate 520 in the first direction DR1.

The first moving block 720 may move along the first moving rail 710. The first moving block 720 may be disposed on the first moving rail 710 between the first moving rail 710 and the first blocking plate 520. A moving driver (not illustrated) may be disposed inside the first moving block 720, so that the first moving block 720 may be moved along the first moving rail 710 according to a driving of the moving driver. Since the first moving block 720 moves along the first moving rail 710, the first moving block 720 may be moved in the first direction DR1.

The first heating member 730 may be supported by the first moving block 720 and movable in the first direction DR1 along the first moving block 720. The first heating member 730 may extend from the first moving block 720 to the right side (right side in FIG. 2) in the second direction DR2. The first heating member 730 may extend so that an extended end of first heating member 730 is in contact with a same virtual vertical surface as the extended end of the first blocking plate 520. The first heating member 730 may be heated by an induction heating method or may be provided as a cartridge heater, etc., but is not limited thereto. The first heating member 730 may be movable in the first direction DR1 as the first moving block 720 moves along the first moving rail 710, and may be in contact with the deposition material accumulated on the first blocking plate 520. Accordingly, the first heating member 730 may heat the deposition material accumulated on the first blocking plate 520 to vaporize and remove the deposition material. In this way, as the first heating member 730 removes the deposition material accumulated on the first blocking plate 520, the first blocking plate 520 may be cleaned.

The first driver 740 may move the first heating member 730 in the second direction DR2. The first driver 740 may connect the first moving block 720 and the first heating member 730 to each other. The first driver 740 may include multiple stages having different diameters. The first driver 740 may be formed in a state in which a stage having a smaller diameter is inserted into a stage having an arbitrary diameter. For example, the first driver 740 may include a first stage and a second stage, and may be formed in a state in which the second stage is inserted into the first stage. The first stage may be connected to the first moving block 720, and the second stage may be connected to the second driver 750. A separate actuator (not illustrated) may be disposed inside the first driver 740, so that the second stage may be pulled into the interior of the first stage or may be pulled out of the first stage by driving the actuator. The first driver 740 may be disposed inside the first moving block 720. In case that the first driver 740 is disposed inside the first moving block 720, the first heating member 730 may be disposed to be in contact with the first moving block 720. In case that the first stage is moved from the first moving block 720 to the right side (right side in FIG. 5) in the second direction DR2 and the second stage is pulled out from the first stage to the right side in the second direction DR2 by driving the actuator of the first driver 740, the first heating member 730 may be moved from the first moving block 720 to the right side in the second direction DR2.

The second driver 750 may rotate the first heating member 730 so that the extended end of the first heating member 730 is directed to a third direction DR3. The second driver 750 may connect the first driver 740 and the third driver 760 to each other. The second driver 750 may be connected to the second stage of the first driver 740 by a rotation shaft and rotated around a rotation axis. By rotating the second driver 750, the extended end of the first heating member 730 may be rotated to face a lower side (lower side in FIG. 6) in the third direction DR3. In other words, the extended end of the first heating member 730 may be rotated to face the deposition nozzle 430 by driving the second driver 750. A separate rotation motor (not illustrated) may be connected to the rotation shaft, so that the second driver 750 may be rotated by driving the rotation motor. The third direction DR3 may be defined as a direction vertically orthogonal to the first and second directions DR1 and DR2.

The third driver 760 may move the first heating member 730 in the third direction DR3. The third driver 760 may connect the second driver 750 and the first heating member 730 to each other. The third driver 760 may be disposed inside the second driver 750. A separate actuator (not illustrated) may be disposed inside the third driver 760, so that the third driver 760 may be pulled out from the inside of the second driver 750 by driving the actuator. In case that the third driver 760 is disposed inside the second driver 750, the first heating member 730 may be disposed to be in contact with the second driver 750. In case that the actuator of the third driver 760 is driven and the third driver 760 is pulled out from the second driver 750 toward the lower side (lower side in FIG. 7) in the third direction DR3, the first heating member 730 may be moved to the lower side in the third direction DR3 from the second driver 750 and inserted into the spray passage 431 of the deposition nozzle 430. In this way, as the first heating member 730 is inserted into the spray passage 431 of the deposition nozzle 430, the deposition material accumulated in the spray passage 431 of the deposition nozzle 430 may be heated to vaporize and remove the deposition material.

The second cleaning module 800 may remove the deposition material accumulated on the second blocking plate 620. The second cleaning module 800 may be disposed below the second blocking plate 620. The second cleaning module 800 may include a second moving rail 810, a second moving block 820, and a second heating member 830.

The second moving rail 810 may provide a path along which the second moving block 820 moves. The second moving rail 810 may be disposed below the second blocking plate 620 to be spaced apart from the second blocking plate 620 by a distance. The second moving rail 810 may extend in the first direction DR1 along the second blocking plate 620. In other words, the second moving rail 810 may extend from a side (lower side in FIG. 2) of the second blocking plate 620 in the first direction DR1 to another side (upper side in FIG. 2) of the second blocking plate 620 in the first direction DR1. An extended length of the second moving rail 810 may be less than the extended length of the second blocking plate 620 in the first direction DR1.

The second moving block 820 may move along the second moving rail 810. The second moving block 820 may be disposed on the second moving rail 810 between the second moving rail 810 and the second blocking plate 620. A moving driver (not illustrated) may be disposed inside the second moving block 820, so that the second moving block 820 may be moved along the second moving rail 810 according to a driving of the moving driver. Since the second moving block 820 moves along the second moving rail 810, the second moving block 820 may be moved in the first direction DR1.

The second heating member 830 may be supported by the second moving block 820 and movable in the first direction DR1 along the second moving block 820. The second heating member 830 may extend from the second moving block 820 to the left side (left side in FIG. 2) in the second direction DR2. The second heating member 830 may extend so that an extended end of the second heating member 830 is in contact with a same virtual vertical surface as the extended end of the second blocking plate 620. The second heating member 830 may be heated by an induction heating method or may be provided as a cartridge heater, etc., but is not limited thereto. The second heating member 830 may be movable in the first direction DR1 as the second moving block 820 moves along the second moving rail 810, and may be in contact with the deposition material accumulated on the second blocking plate 620. Accordingly, the second heating member 830 may heat the deposition material accumulated on the second blocking plate 620 to vaporize and remove the deposition material. In this way, as the second heating member 830 removes the deposition material accumulated on the second blocking plate 620, the second blocking plate 620 may be cleaned.

Hereinafter, a cleaning method of a depositing apparatus according to an embodiment of the disclosure will be described with reference to the accompanying drawings.

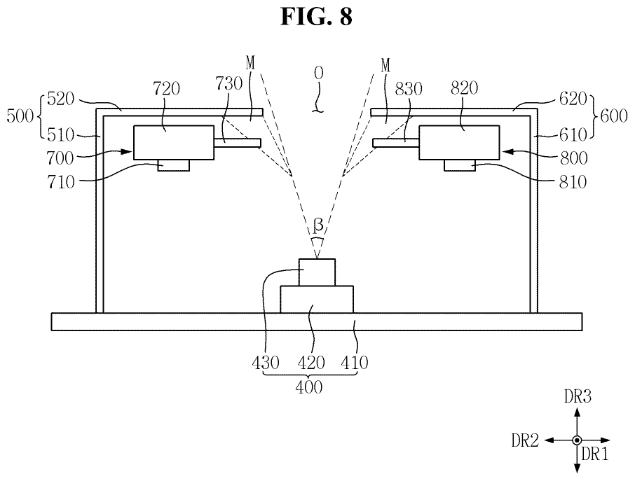

FIG. 8 is a schematic cross-sectional view illustrating a state in which a spray angle of a deposition nozzle is changed due to a deposition material accumulated on the spray angle limiting portion of FIG. 1.

Referring to FIG. 8, as the usage time of the depositing apparatus 10 elapses, the deposition material sprayed from the deposition nozzle 430 may accumulate on a lower portion of the first blocking plate 520 of the first spray angle limiting portion 500 and a lower portion of the second blocking plate 620 of the second spray angle limiting portion 600. A spray angle β of the deposition nozzle 430 may be reduced by the deposition material M accumulated on the lower portion of the first blocking plate 520 and the lower portion of the second blocking plate 620. If the spray angle β of the deposition nozzle 430 is reduced, the area and deposition thickness where the deposition material is deposited on the substrate S may change, which may cause defects in the organic light emitting display device. As the deposition material M accumulated on the lower portion of the first blocking plate 520 and the lower portion of the second blocking plate 620 may fall to the deposition nozzle 430, the spray passage 431 of the deposition nozzle 430 may be closed. Since the defects in the organic light emitting display device may be caused by the deposition material M accumulated on the lower portion of the first blocking plate 520 and the lower portion of the second blocking plate 620 and the deposition material accumulated in the spray passage 431 of the deposition nozzle 430, there is a need to remove the deposition material M accumulated on the first blocking plate 520, the second blocking plate 620, and the deposition nozzle 430.

The cleaning method of the depositing apparatus according to an embodiment of the disclosure may include a spray angle limiting portion cleaning step and a deposition nozzle cleaning step.

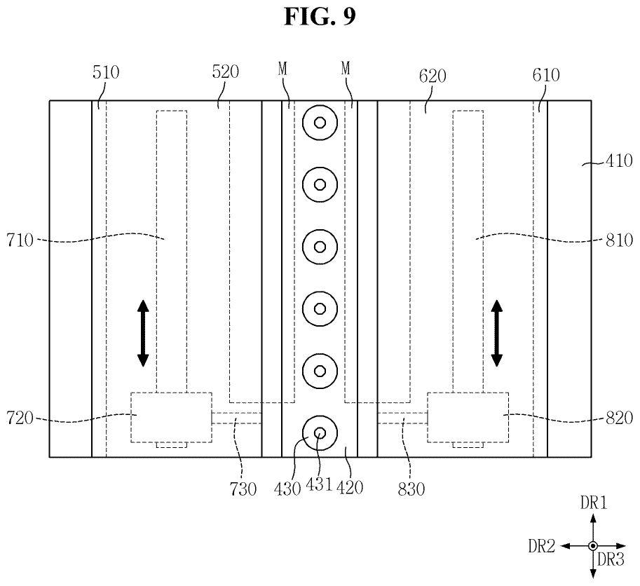

FIG. 9 is a plan view illustrating a state in which a first cleaning module and a second cleaning module in FIG. 2 are moved in a first direction.

Referring to FIG. 9, the spray angle limiting portion cleaning step may be a step in which the first cleaning module 700 and the second cleaning module 800 are moved in the first direction DR1 along the first spray angle limiting portion 500 and the second spray angle limiting portion 600 below the first spray angle limiting portion 500 and the second spray angle limiting portion 600.

In the spray angle limiting portion cleaning step, as the first moving block 720 of the first cleaning module 700 is moved in the first direction DR1 along the first moving rail 710, the first heating member 730 may be moved in the first direction DR1 below the first blocking plate 520. The first heating member 730 may be moved below the first blocking plate 520 and be in contact with the deposition material M accumulated on the lower side of the first blocking plate 520. The first heating member 730 in contact with the deposition material M accumulated on the lower side of the first blocking plate 520 may vaporize the deposition material M accumulated on the lower side of the first blocking plate 520 and remove the deposition material M from the first blocking plate 520, thereby clean the first blocking plate 520. The first moving block 720 may be reciprocated from a side (lower side in FIG. 9) of the first moving rail 710 to another side (upper side in FIG. 9) of the first moving rail 710 to reciprocate the first heating member 730 in the first direction DR1 below the first blocking plate 520.

In the spray angle limiting portion cleaning step, as the second moving block 820 of the second cleaning module 800 is moved in the first direction DR1 along the second moving rail 810, the second heating member 830 may be moved in the first direction DR1 below the second blocking plate 620. The second heating member 830 may be moved below the second blocking plate 620 and be in contact with the deposition material M accumulated on the lower side of the second blocking plate 620. The second heating member 830 in contact with the deposition material M accumulated on the lower side of the second blocking plate 620 may vaporize the deposition material M accumulated on the lower side of the second blocking plate 620 and remove the deposition material M from the second blocking plate 620, thereby clean the second blocking plate 620. The second moving block 820 may be reciprocated from a side (lower side in FIG. 9) of the second moving rail 810 to another side (upper side in FIG. 9) of the second moving rail 810 to reciprocate the second heating member 830 in the first direction DR1 below the second blocking plate 620.

In the spray angle limiting portion cleaning step, the first cleaning module 700 and the second cleaning module 800 may be moved separately or may be moved equally in parallel positions, but are not limited thereto.

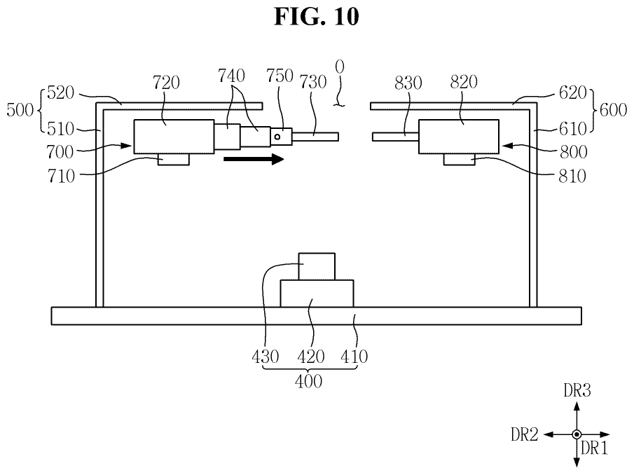

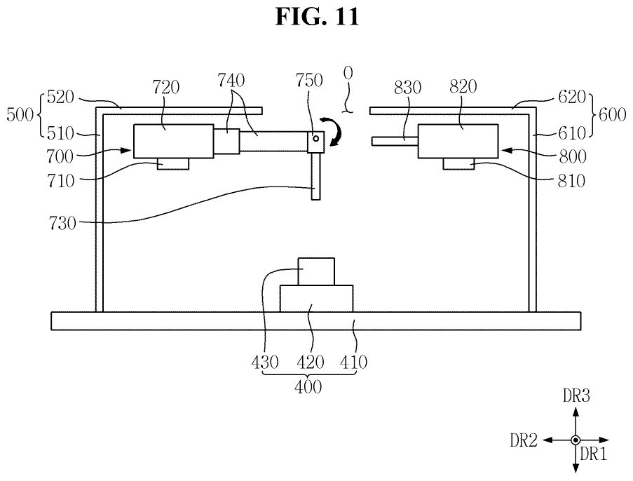

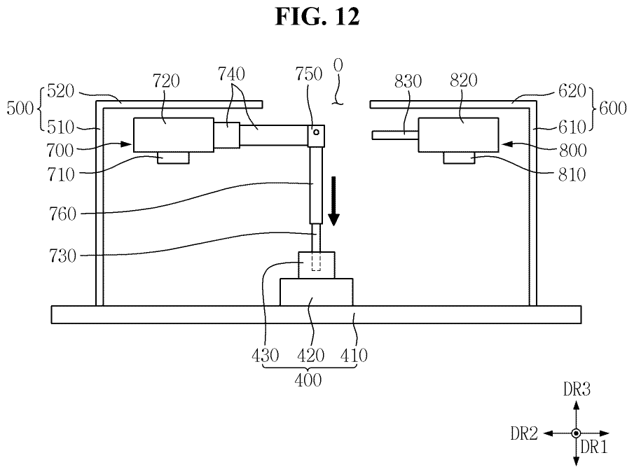

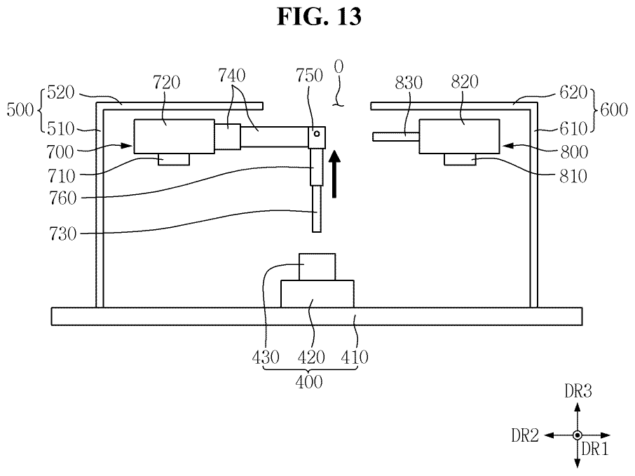

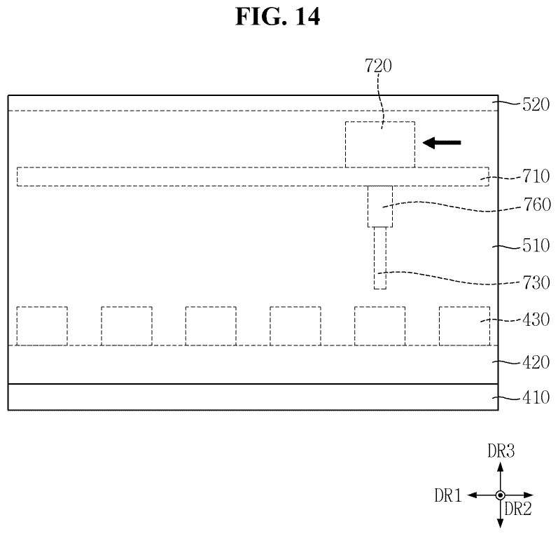

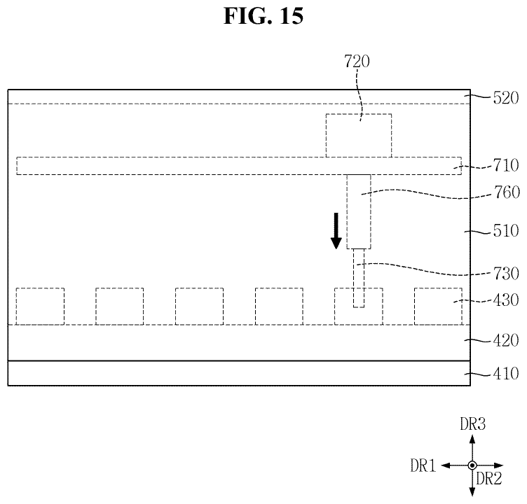

FIG. 10 is a schematic cross-sectional view illustrating a state in which a heating member is moved in a second direction by the first driver in the front view of FIG. 2. FIG. 11 is a schematic cross-sectional view illustrating a state in which the heating member is rotated to face a third direction by the second driver in FIG. 10. FIG. 12 is a schematic cross-sectional view illustrating a state in which the heating member is moved in the third direction by the third driver in FIG. 11 and inserted into a deposition nozzle. FIG. 13 is a schematic cross-sectional view illustrating a state in which the heating member is moved in the third direction by the third driver in FIG. 12 and pulled out from the deposition nozzle. FIG. 14 is a schematic cross-sectional view illustrating a state in which a first moving block is moved in the first direction along a first moving rail in the left side view of FIG. 13. FIG. 15 is a schematic cross-sectional view illustrating a state in which the heating member is moved in the third direction by the third driver in FIG. 14 and inserted into another deposition nozzle.

Referring to FIGS. 10 to 15, the deposition nozzle cleaning step may be a step in which the first heating member 730 is inserted into the spray passage 431 of the deposition nozzle 430 to remove the deposition material M accumulated inside the spray passage 431 of the deposition nozzle 430. The deposition nozzle cleaning step may include a first driving step, a second driving step, a third driving step, a fourth driving step, a fifth driving step, and a sixth driving step.

Referring to FIG. 10, the first driving step may be a step in which the first heating member 730 is moved to the right side (right side in FIG. 10) in the second direction DR2 by the first driver 740 and positioned above the deposition nozzle 430. In the first driving step, as the actuator of the first driver 740 is driven, the first stage may be moved from the first moving block 720 to the right side (right side in FIG. 5) in the second direction DR2, and as the second stage is pulled out from the first stage to the right side in the second direction DR2, the first heating member 730 may be positioned above the deposition nozzle 430.

Referring to FIG. 11, the second driving step may be a step in which the first heating member 730 positioned above the deposition nozzle 430 is rotated to face the deposition nozzle 430 by the second driver 750. In the second driving step, the second driver 750 may be rotated around the rotation shaft, so that the extended end of the first heating member 730 may be rotated to face the lower side (lower side in FIG. 11) in the third direction DR3. In other words, in the second driving step, the extended end of the first heating member 730 may be rotated to face the deposition nozzle 430 by the second driver 750.

Referring to FIG. 12, the third driving step may be a step in which the first heating member 730 rotated to face the deposition nozzle 430 is inserted into the deposition nozzle 430 by the third driver 760. In the third driving step, as the actuator of the third driver 760 is driven, the third driver 760 may be moved from the second driver 750 to the lower side (lower side in FIG. 12) in the third direction DR3, and as the third driver 760 is moved to the lower side in the third direction DR3, the first heating member 730 may be inserted into the spray passage 431 of the deposition nozzle 430. The first heating member 730 inserted into the spray passage 431 of the deposition nozzle 430 may heat the deposition material accumulated in the spray passage 431 of the deposition nozzle 430 and vaporize and remove the deposition material.

Referring to FIG. 13, the fourth driving step may be a step in which the first heating member 730 inserted into the spray passage 431 of the deposition nozzle 430 is pulled out from the spray passage 431 of the deposition nozzle 430 by the third driver 760. In the fourth driving step, as the actuator of the third driver 760 is driven, the third driver 760 may be moved to the upper side (upper side in FIG. 13) in the third direction DR3, and as the third driver 760 is moved to the upper side in the third direction DR3, the first heating member 730 may be pulled out from the spray passage 431 of the deposition nozzle 430.

Referring to FIG. 14, the fifth driving step may be a step in which the first moving block 720 is moved along the first moving rail 710 so that the first heating member 730 pulled out from the spray passage 431 of the deposition nozzle 430 is positioned above another adjacent deposition nozzle 430. In the fifth driving step, as the moving driver is driven so that the first heating member 730 is positioned above another deposition nozzle 430 adjacent to the deposition nozzle 430 into which the first heating member 730 was inserted, the first moving block 720 may be moved in the left side (left side in FIG. 14) in the first direction DR1 along the first moving rail 710.

Referring to FIG. 15, the sixth driving step may be a step in which the first heating member 730 positioned above another deposition nozzle 430 is inserted into the another deposition nozzle 430 by the third driver 760. In the sixth driving step, as the actuator of the third driver 760 is driven, the third driver 760 may be moved to the lower side (lower side in FIG. 15) in the third direction DR3, and as the third driver 760 is moved to the lower side in the third direction DR3, the first heating member 730 may be inserted into the spray passage 431 of the another deposition nozzle 430. The first heating member 730 inserted into the spray passage 431 of the another deposition nozzle 430 may heat the deposition material accumulated in the spray passage 431 of the another deposition nozzle 430 and vaporize and remove the deposition material. In case that the deposition material accumulated inside another deposition nozzle 430 is removed, the fifth driving step and the sixth driving step may be repeatedly performed to remove all the deposition materials accumulated in the deposition nozzles 430.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A depositing apparatus comprising:
a deposition source including at least one deposition nozzle that sprays a deposition material;
a spray angle limiting portion spaced apart from the deposition source and limiting a spray angle of the deposition material sprayed from the at least one deposition nozzle; and
a cleaning module disposed between the deposition source and the spray angle limiting portion and heating the deposition material accumulated on the spraying angle limiting portion.

2. The depositing apparatus of claim 1, wherein the cleaning module is disposed closer to the spray angle limiting portion than the deposition source.

3. The depositing apparatus of claim 1, wherein
the at least one deposition nozzle includes a plurality of deposition nozzles,
the plurality of deposition nozzles are arranged in a first direction, and
the cleaning module is disposed to be movable in the first direction.

4. The depositing apparatus of claim 3, wherein the spray angle limiting portion includes:
an extension plate extending to an upper direction from the deposition source; and
a blocking plate extending from the extension plate in a second direction and forming an open area through which the deposition material passes.

5. The depositing apparatus of claim 4, wherein the second direction is a direction horizontally orthogonal to the first direction.

6. The depositing apparatus of claim 5, wherein the open area is disposed above the plurality of deposition nozzles and extends in the first direction.

7. The depositing apparatus of claim 6, wherein the cleaning module includes:
a moving rail extending in the first direction below the blocking plate;
a moving block disposed on the moving rail and moving along the moving rail; and
a heating member extending from the moving block in the second direction.

8. The depositing apparatus of claim 7, wherein the cleaning module further includes a first driver connecting the moving block and the heating member and moving the heating member in the second direction.

9. The depositing apparatus of claim 8, wherein the cleaning module further includes a second driver connecting the first driver and the heating member and rotating the heating member so that an extended end of the heating member faces a third direction.

10. The depositing apparatus of claim 9, wherein the third direction is a direction vertically orthogonal to the first direction and the second direction.

11. The depositing apparatus of claim 10, wherein the cleaning module further includes a third driver connecting the second driver and the heating member and moving the heating member in the third direction.

12. The depositing apparatus of claim 11, wherein the heating member is moved by the third driver and inserted into one of the plurality of deposition nozzles.

13. The depositing apparatus of claim 4, wherein
the extension plate includes a plurality of extension plates,
the plurality of extension plates include a first extension plate and a second extension plate,
the first extension plate extends in an upper direction from a side of the deposition source, and
the second extension plate extends in an upper direction from another side of the deposition source so that the plurality of deposition nozzles are disposed between the first extension plate and the second extension plate.

14. The depositing apparatus of claim 13, wherein
the blocking plate includes a plurality of blocking plates,
the plurality of blocking plates include a first blocking plate and a second blocking plate,
the first blocking plate extends from the first extension plate in the second direction so as to be directed to an upper side of the plurality of deposition nozzles,
the second blocking plate extends from the second extension plate in the second direction to face the first blocking plate, and
an extended end of the first blocking plate and an extended end of the second blocking plate are spaced apart from each other, so that the open area is formed between the first blocking plate and the second blocking plate.

15. The depositing apparatus of claim 14, wherein
the cleaning module includes a plurality of cleaning modules,
the plurality of cleaning modules include a first cleaning module and a second cleaning module,
the first cleaning module is disposed below the first blocking plate, and
the second cleaning module is disposed below the second blocking plate.

16. A cleaning method of a depositing apparatus, the cleaning method comprising:
cleaning a spray angle limiting portion including moving a cleaning module disposed below the spray angle limiting portion that limits a spray angle of a deposition material sprayed from a deposition nozzle along the spray angle limiting portion, and removing the deposition material accumulated on the spray angle limiting portion by a heating member of the cleaning module; and
cleaning the deposition nozzle including inserting the heating member into the deposition nozzle to remove the deposition material accumulated in the deposition nozzle.

17. The cleaning method of claim 16, wherein
the deposition nozzle includes a plurality of deposition nozzles arranged in a first direction,
the spray angle limiting portion includes a blocking plate that forms an open area through which the deposition material passes extending in the first direction above the plurality of deposition nozzles, and
the cleaning of the spray angle limiting portion includes moving the cleaning module in the first direction below the blocking plate.

18. The cleaning method of claim 17, wherein
the cleaning module further includes:
a moving rail extending in the first direction below the blocking plate; and
a moving block supporting the heating member and disposed on the moving rail to move along the moving rail, and
the cleaning of the spray angle limiting portion includes moving the moving block along the moving rail.

19. The cleaning method of claim 18, wherein
the cleaning module further includes:
a first driver moving the heating member in a second direction horizontally orthogonal to the first direction and positioning the heating member above the plurality of deposition nozzles;
a second driver rotating the heating member to a third direction vertically orthogonal to the first direction and the second direction so that the heating member faces the plurality of deposition nozzles; and
a third driver moving the heating member in the third direction so that the heating member is inserted into one of the plurality of deposition nozzles, and
the cleaning of the deposition nozzle further includes:
moving the heating member in the second direction by the first driver and positioning the heating member above the plurality of deposition nozzles;
rotating the heating member positioned above the one of the plurality of deposition nozzles by the second driver to face the one of the plurality of deposition nozzles; and
inserting the heating member rotated to face the one of the plurality of deposition nozzles into the one of the plurality of deposition nozzles by the third driver.

20. The cleaning method of claim 19, wherein the cleaning of the deposition nozzle further includes:
moving the heating member inserted into the one of the plurality of deposition nozzles in the third direction by the third driver so that the heating member is pulled out from the one of the plurality of deposition nozzles;
moving the moving block along the moving rail so that the heating member pulled out from the one of the plurality of deposition nozzles is positioned above another one of the plurality of deposition nozzles adjacent to the one of the plurality of deposition nozzles; and
inserting the heating member positioned above the another one of the plurality of deposition nozzles into the another one of the plurality of deposition nozzles by the third driver.
